(19) United States
(12) Patent Application Publication
(10) Pub. No.: US 2025/0226211 A1
(43) Pub. Date: Jul. 10, 2025

(54) INCREASED ETCH RESISTANCE OF NITRIDE LAYERS USING CHEMICAL VAPOR DEPOSITION AND HOT ION IMPLANTATION

(71) Applicant: Applied Materials, Inc., Santa Clara, CA (US)

(72) Inventors: Rajesh PRASAD, Lexington, MA (US); Fernando Antonio REBOLLEDO USCANGA, Rockport, MA (US); Shan TANG, Middleton, MA (US); Wayne CHEN, Newton, MA (US); Godwin John NTUK, Lynn, MA (US); Jialiang WANG, Milpitas, CA (US); Guangyan ZHONG, Sunnyvale, CA (US); Aditya SUNDARAM, Santa Clara, CA (US); Shweta HARDIKAR, Milpitas, CA (US); Edwin A. AREVALO, Beverly, MA (US); Kyu-Ha SHIM, Andover, MA (US)

(73) Assignee: Applied Materials, Inc., Santa Clara, CA (US)

(21) Appl. No.: 19/007,902

(22) Filed: Jan. 2, 2025

Related U.S. Application Data
(60) Provisional application No. 63/617,687, filed on Jan. 4, 2024.

(51) Int. Cl. H01L 21/02; C23C 14/48; C23C 14/58; H01L 21/3115

(52) U.S. Cl. CPC H01L 21/02321; C23C 14/48; C23C 14/5806; H01L 21/02694; H01L 21/31155

(57) ABSTRACT

A process to generate an etch-resistant nitride layer is provided. The process may include providing a substrate, the substrate including a silicon nitride layer formed by PECVD at an elevated deposition temperature, heating the substrate to an elevated implant temperature, and performing a hot implant by implanting the substrate at the elevated implant temperature, wherein an implanted silicon nitride layer is formed. The process may also include annealing the substrate after the hot implant at an elevated anneal temperature, wherein a relative etch rate of the implanted silicon nitride layer is reduced with respect to an unimplanted silicon nitride layer.

### RELATED APPLICATIONS

This application claims priority to U.S. provisional patent application Ser. No. 63/617,687, filed Jan. 4, 2024, entitled INCREASED ETCH RESISTANCE OF NITRIDE LAYERS USING CHEMICAL VAPOR DEPOSITION AND HOT ION IMPLANTATION, and incorporated by reference in its entirety.

### FIELD

The present embodiments relate to device processing, and more particularly, to improved nitride layers for electronic devices.

### BACKGROUND

In the present day, insulator layer, such as nitride layers may be deployed in various stages of device processing. In some examples, nitride layers may be used as stress liners in transistor devices while in other examples the nitride layers may be used as hardmasks. Nitride layers may be deposited by various methods including physical vapor deposition (CVD) and chemical vapor deposition (CVD). Depending upon the deposition process, the properties of the nitride layer may vary.

In known applications, silicon nitride (SiN) layers are used for hard masks that are designed to protect underlying portions of a device during subsequent device processing. Note that ‘SiN’ as used herein may refer generally to a silicon nitride layer, and not to a particular stochiometry. Thus a “SiN layer” or “silicon nitride layer” may be understood to represent a layer having a mixture predominantly of Si and N, a Si₃N₄ layer, or layer of similar composition that may include other minor constituents such as hydrogen. As such, hard masks are designed to resist etchants that may be purposefully employed to etch unprotected areas of a substrate that are subjacent to the hard mask. Nonetheless, during an etching process to etch an underlying substrate, a certain thickness of a hardmask layer is generally removed. In order to provide sufficient process margin for performing such etching processes, hardmask layers are deposited with sufficient thickness to ensure that at the end of an etching process to etch designated regions of the substrate, some hardmask layer remains, so that no portion of the substrate regions to be protected are inadvertently etched.

However, a disadvantage resulting from the use of relatively thicker hard mask layers is the decrease in patterning fidelity in terms of line width roughness or line edge roughness, as well as potential line wriggling.

With respect to these and other considerations the present disclosure is provided.

### BRIEF SUMMARY

In one embodiment, a process to generate an etch-resistant nitride layer is provided. The process may include providing a substrate, the substrate including a silicon nitride layer formed by PECVD at an elevated deposition temperature, heating the substrate to an elevated implant temperature, and performing a hot implant by implanting the substrate at the elevated implant temperature, wherein an implanted silicon nitride layer is formed. The process may also include annealing the substrate after the hot implant at an elevated anneal temperature, wherein a relative etch rate of the implanted silicon nitride layer is reduced with respect to an unimplanted silicon nitride layer.

In another embodiment, a process to generate an etch-resistant patterned silicon nitride layer may include providing a substrate having a high temperature PECVD silicon nitride layer, patterning the high temperature PECVD silicon nitride layer to form a patterned silicon nitride layer, and heating the substrate to an elevated implant temperature. The process may also include performing a hot implant by implanting the substrate at the elevated implant temperature, wherein the patterned silicon nitride layer is exposed to an implant species, wherein, after the hot implant, a relative etch rate of the patterned silicon nitride layer is reduced with respect to an unimplanted silicon nitride layer.

### BRIEF DESCRIPTION OF THE DRAWINGS

FIGS. 1A-1F depict exemplary stages of a substrate during processing, according to embodiments of the disclosure;

FIGS. 2A-2F depict exemplary stages of a substrate during processing, according to embodiments of the disclosure;

FIGS. 3A-3B are composite illustrations presenting experimental data for etch rate control of nitride layers, according to various embodiments of the disclosure; and

FIG. 4 presents a process flow, according to some embodiments.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

In accordance with some embodiments, novel processing techniques entail implantation of CVD-deposited layers, and in particular, nitride layers formed by CVD. According to various embodiments of the disclosure, these nitride layers may be employed as liners, hardmasks, and the like, for devices, such as semiconductor devices, at various stages of processing. Example nitride layers include SiN, deposited by a plasma-enhanced CVD (PECVD) technique. As detailed in the disclosure to follow, PECVD nitride layers may be suitably treated to provide more process window for controlling device properties, where the treatment may include UV exposure and hot ion implantation.

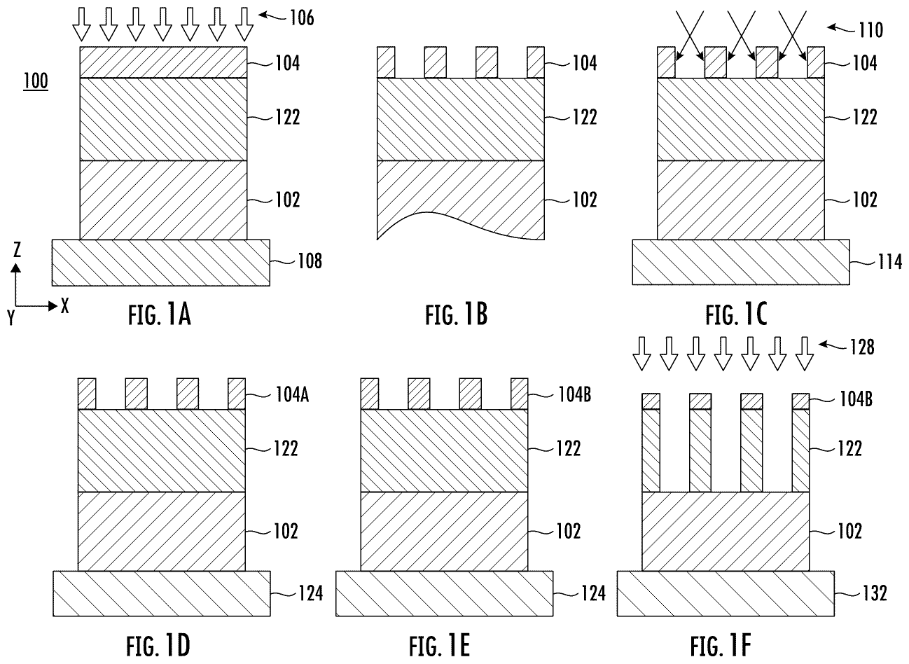

FIG. 1A-1E show exemplary stages of a substrate during processing for enhancing etch rate resistance, according to embodiments of the disclosure. FIG. 1F depicts a further substrate processing operation. Turning to FIG. 1A there is shown one stage of processing a device 100. The device 100 may represent a semiconductor device that includes a plurality of layers, devices, and other features, which structures may be at various stages of fabrication, including memory devices, logic devices, CMOS devices, and so forth. For purposes of illustration, in one example, the device 100 may include a plurality of device structures or layers, shown as layer 122. These devices or layers may be formed on or within an underlying substrate, shown as substrate 102. In one example, the layer 122 may represent an oxide layer to be patterned in the device 100. In other embodiments, the layer 122 may represent any suitable layer to be processed as described below with respect to FIGS. 1A to 4, including nitride layer, insulator layer, metal layer, or semiconductor layer.

In the operation depicted in FIG. 1A, a layer 104 is formed using depositing species 106. In one example, the depositing species 106 are provided in a processing apparatus that performs a PECVD process. In some embodiments, the layer 104 is a silicon nitride (SiN) layer. In particular embodiments, the PECVD process used to deposit the layer 104 may employ a capacitively coupled plasma, operating at a suitable frequency, such as 13.6 MHz, as known in the art. In some embodiments suitable precursor gases for depositing a silicon nitride layer to act as layer 104 include silane (SiH₄), nitrogen (N₂), and ammonia (NH₃).

According to embodiments of the disclosure, the flow rates of the precursor gases and the power delivered by the plasma source are used to modify the composition, density and deposition rate of an SiN film used as layer 104. Control of these latter three parameters in turn, may control the etch resistance in the layer 104, as-deposited. Therefore by modulating the gas flows or by adjusting the power delivered by the plasma source, the etching properties of the layer 104 at the stage in FIG. 1A may be controlled.

According to various embodiments of the disclosure, the layer 104 is deposited by a PECVD process at elevated substrate temperature, and in particular in a range between 300° C. and 500° C., between 350° C. and 450° C., and in some embodiments, at a temperature in a range of 390° C. to 410° C. Again, by varying the substrate temperature during deposition of the layer 104, the properties in the layer 104 will vary.

According to particular non-limiting embodiments of the disclosure, the substrate 102 may be place upon a heater 108 that heats the substrate during the deposition of layer 104, where the heater is situated at the bottom of a PECVD chamber with a faceplate at the top of the PECVD chamber being separated from the substrate 102 by approximately 1 cm. By adjusting the spacing between faceplate and substrate 100, the stress state of layer 104 may also be adjusted.

In various embodiments, the layer 104 may be deposited at a suitable thickness to act as a hard mask for subsequent processing operations. Note that in various embodiments, the substrate 102 may be exposed to ultraviolet radiation (UV) after deposition in order to adjust the properties in the layer 104, as deposited.

Turning to FIG. 1B, there is shown a subsequent instance or stage that takes place after the layer 104 has been deposited. At this stage, the layer 104 has been patterned to form a series of structures that are separated by openings in the layer 104, exposing the subjacent layer, layer 122. The patterning of a PECVD layer, such as a nitride layer may take place using known lithographic and etching processes.

Turning to FIG. 1C, there is shown a subsequent instance or stage that takes place after the layer 104 has been patterned. Additionally, the substrate 102 is heated to an elevated temperature. In some embodiments the elevated temperature may be between 150° C. and 700° C. The substrate 102 may be heated by any suitable means, such as using a heated platen, heated by convection, heated in an oven, heated using a radiation source, and so forth. In the example of FIG. 1C the substrate 102 is shown as disposed on a platen 114, which platen may be a heated platen.

When the substrate 102 has been heated to the elevated temperature, as shown in FIG. 1C, a hot implant is conducted to implant an implant species 110 into materials on the substrate 102. In this embodiment, a hot implant is conducted as a hot angled implant, where the angle of the trajectories of implant species 110 with respect to a perpendicular to a main plane of the substrate (X-Y plane according to the Cartesian coordinate system shown) is between 0.1 degrees and 80 degrees. According to various non-limiting embodiments, when an angled implant is to be implemented, the wafer may need to be rotated in the X-Y plane, according to a suitable rotation sequence. The rotation sequence depends upon the feature that is being implanted. For example, for a line structure the angled implant needs to be done at a rotation=0 degrees and 180 degrees. If the feature is a circle, i.e., a via, then angled implant needs to be done at various rotation angles: e.g., 0 degrees, 90 degrees, 180 degrees, 270 degrees. The number of rotations can be increased from 4 as just explained to as many as is needed to uniformly implant the feature. For example, to do 8 rotations, the wafer would be rotated every 45 degrees, or 16 rotations, the wafer would be rotated every 22.5 degrees and so on.

According to various non-limiting embodiments, the implant species 110 may be ions that have an energy in the range 0.2 keV to 120 keV. Suitable implant species according to different embodiments include at least one of: carbon, nitrogen, silicon, germanium, helium, neon, and argon. The energy and angle of incidence of the implant species 110 may be chosen so that the implant species 110 are incorporated in targeted layers of the device 100, and not incorporated, or incorporated to a lesser extent in other layers. For example, in the instance of FIG. 1C, the energy of the implant species 110 may be adjusted so the implant species that strike the layer 104 are incorporated in the layer 104. Moreover, depending upon the angle of incidence of the implant species 110 and the separation of the patterned features of the layer, the implant species 110 may impact the layer 122 to a lesser extent than the impact on layer 104, or may not impact the layer 122 at all. In some embodiments, the dose of the implant species in the layer 104 is chosen so that an implant concentration of 1E20/cm³ up to 3.5E22/cm³ is generated in the layer 104.

Turning to FIG. 1D, there is shown a subsequent instance after the completion of the stage of FIG. 1C. At this stage, as a result of the hot ion implant at the stage of FIG. 1C, an implanted layer 104A has been formed over the device 100. As further shown in FIG. 1D, the implanted layer 104A is subjected to a post-implant anneal. This operation of FIG. 1D is depicted in this embodiment, but in other embodiments, the post-implant anneal may be omitted for other applications that employ hot implantation to reduce (improve) the SiN etch rate. The anneal may be conducted in any suitable apparatus, including furnace anneal, anneal on a platen, rapid thermal anneal, anneal using radiation, and so forth. A platen 124 is depicted in FIG. 1D merely for the purposes of simplicity. In various embodiments, the anneal may be conducted at temperatures ranging from 125° C. to 1100° C., for periods of one millisecond up to several minutes.

Turning to FIG. 1E there is shown subsequent instance after post-implant anneal. At this stage, as a result of the post-implant anneal at the stage of FIG. 1D, an implanted and post-anneal layer 104B has been formed over the device 100.

Turning to FIG. IF there is shown a subsequent instance where an etch process is performed to pattern the layer 122. At this point the original state of layer 104 has been transformed into etch hardened layer 104B, as a result of the hot implantation and post-implant annealing operations depicted in FIG. 1C and FIG. 1D, respectively. In some non-limiting embodiments, where etch hardened layer 104B is a nitride hard mask layer, the layer 122 may be an oxide layer. The etch process may be carried out by etch species 128. In some examples, the etch species 128 may be provided in a directional etch, including a reactive ion etching (RIE) process were the substrate 102 is disposed on a platen 132, which platen maybe a heated platen, while in some examples, the etch species 128 may be provided in a wet etch process. The etch species 128 may be provided in a known recipe that is arranged to selectively etch the layer 122 with respect to the etch hardened layer 104B. As a result of processing of FIG. 1C and FIG. 1D, the etch hardened layer 104B may etch slower than the etch rate of the layer 104, when not subjected to hot implantation and post-implant annealing. Thus, for a given etch period, a much larger thickness of layer 122 may be etched as compared to a thickness of layer 104. In particular embodiments, this lower etch rate as compared to unimplanted hard mask layers, allows the layer 104 to be provided at a lesser thickness than in known hard mask layers, in order to accomplish a targeted amount of etching of the layer 122. This lesser thickness of layer 104 has several benefits, including the reduction in line edge roughness (LER) and reduction in linewidth roughness (LWR) for patterned features that are patterned using a hardmask layer that is not subjected to hot implantation and post-implant annealing.

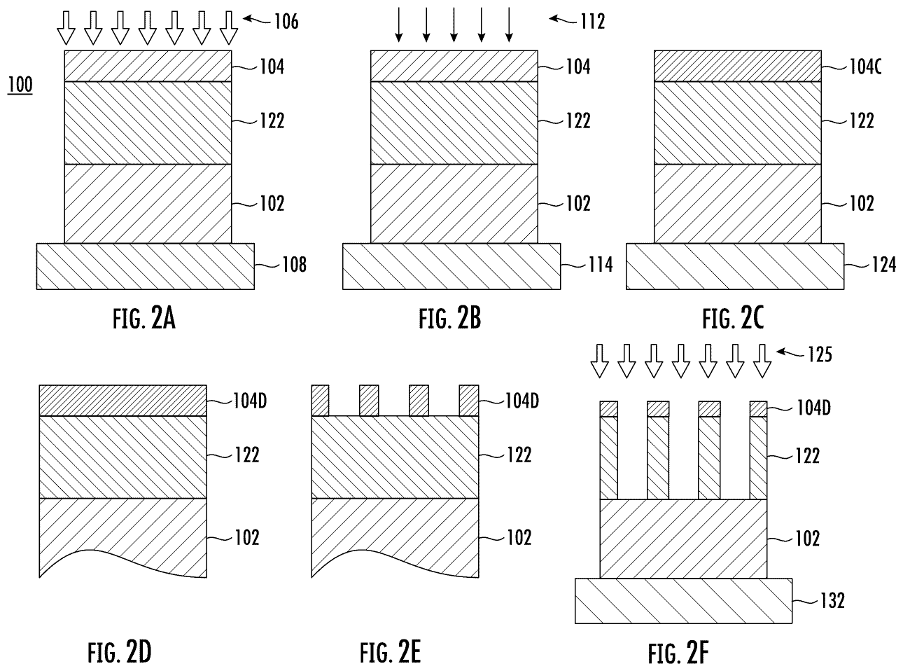

FIG. 2A-2D show exemplary stages of a substrate during processing for enhancing etch rate resistance, according to additional embodiments of the disclosure. FIG. 2E and FIG. 2F depicts further substrate processing operations. Turning to FIG. 2A there is shown one stage of processing a device 100. In some embodiments, the device 100 may be as described above with respect to FIG. 1A. The processing of FIG. 2A may likewise proceed as described above with respect to FIG. 1A, where a layer 104 is formed using depositing species 106. Note that in various embodiments, the substrate 102 may be exposed to ultraviolet radiation (UV) after deposition in order to adjust the properties in the layer 104, as deposited.

Turning to FIG. 2B, there is shown a subsequent instance or stage that takes place after the layer 104 has been deposited. At this stage, the layer 104 may be arranged in blanket form to cover underlying layers of the substrate 102, including the layer 122. As depicted in FIG. 2B, the substrate 102 is heated to an elevated temperature. In some embodiments the elevated temperature may be between 150° C. and 700° C. The substrate 102 may be heated by any suitable means, such as using a heated platen, heated by convection, heated in an oven, heated using a radiation source, and so forth. In the example of FIG. 2B the substrate 102 is shown as disposed on a platen 114, which platen may be a heated platen.

When the substrate 102 has been heated to the elevated temperature, as shown in FIG. 2B, a hot implant is conducted to implant an implant species 112 into materials on the substrate 102. In this embodiment, a hot implant is conducted as a normal incidence implant, where the angle of the trajectories of implant species 112 with respect to a perpendicular to a main plane of the substrate (X-Y plane according to the Cartesian coordinate system shown) is zero degrees or close to zero degrees, such as less than five degrees from normal. According to various non-limiting embodiments, the implant species 112 may be ions that have an energy in the range 0.2 keV to 120 keV. Suitable implant species according to different embodiments include at least one of: carbon, nitrogen, silicon, germanium, helium, neon, and argon. The energy of the implant species 112 may be chosen so that the implant species 112 are incorporated in targeted layers of the device 100, and not incorporated, or incorporated to a lesser extent in other layers. For example, in the instance of FIG. 2B, the energy of the implant species 112 may be adjusted so the implant species that strike the layer 104 are incorporated in the layer 104. In some embodiments, the dose of the implant species in the layer 104 is chosen so that an implant concentration of 1E20/cm³ up to 3.5E22/cm³ is generated in the layer 104.

Turning to FIG. 2C, there is shown a subsequent instance after the completion of the stage of FIG. 2B. At this stage, as a result of the hot ion implant at the stage of FIG. 2B, an implanted layer 104C has been formed over the device 100. As further shown in FIG. 2C, the implanted layer 104C is subjected to a post-implant anneal. This operation of FIG. 2C is depicted in this embodiment, but in other embodiments, the post-implant anneal may be omitted for other applications that employ hot implantation to reduce (improve) the SiN etch rate. The anneal may be conducted in any suitable apparatus, including furnace anneal, anneal on a platen, rapid thermal anneal, anneal using radiation, and so forth. A platen 124 is depicted in FIG. 2C merely for the purposes of simplicity. In various embodiments, the anneal may be conducted at temperatures ranging from 125° C. to 1100° C., for periods of one millisecond up to several minutes.

Turning to FIG. 2D, there is shown a subsequent instance or stage that takes place after the layer 104 has been implanted and subject to post-implant anneal to form the etch-hardened layer 104D.

Turning to FIG. 2E, at this stage, the etch-hardened layer 104D has been patterned to form a series of structures that are separated by openings in the etch-hardened layer 104, exposing the subjacent layer, layer 122. Note that in examples where the etch-hardened layer 104D is a nitride layer, the lithographic patterning and etching of the etch-hardened layer 104D may have to be adjusted from known processes to account for the hardened nature of the etch-hardened layer 104D.

Turning to FIG. 2F there is shown a subsequent instance where an etch process is performed to pattern the layer 122. In some non-limiting embodiments, where etch-hardened layer 104D is a nitride hard mask layer, the layer 122 may be an oxide layer. The etch process may be carried out by etch species 125, generally as described above with respect to FIG. 2F. Where the substrate 102 is disposed on a platen 132, which maybe a heated platen. As with the embodiment of FIGS. 1A-1F, this lower etch rate of etch-hardened layer 104D as compared to unimplanted hard mask layers, allows the layer 104 to be provided at a lesser thickness than in known hard mask layers, in order to accomplish a targeted amount of etching of the layer 122.

### Experiments

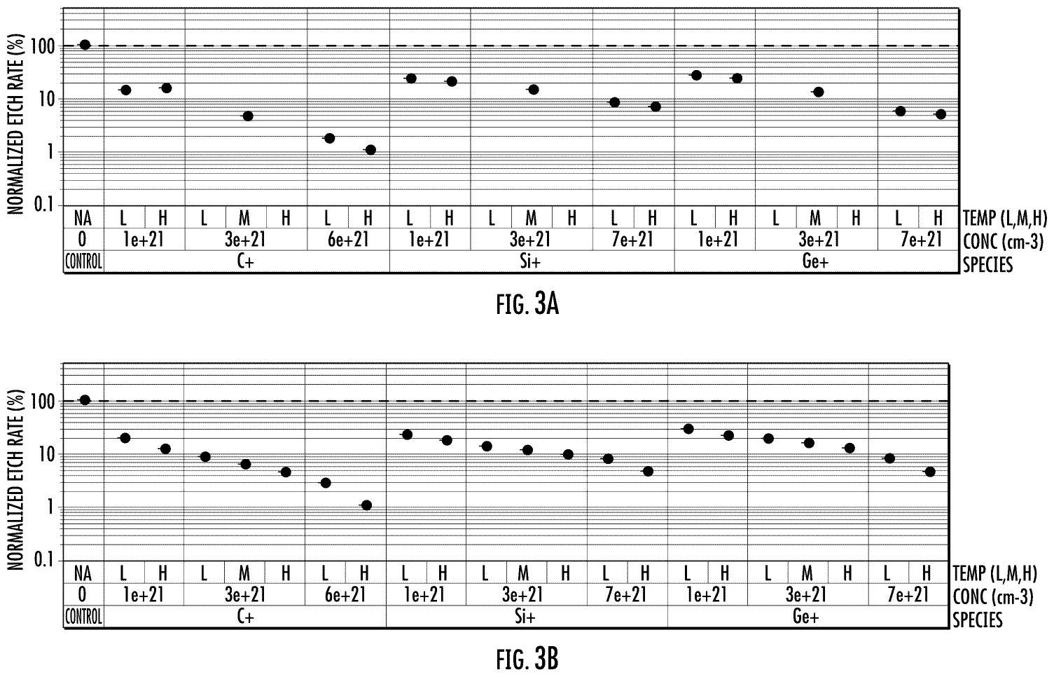

FIGS. 3A-3B are composite illustrations presenting experimental data for etch rate control of nitride layers, according to various embodiments of the disclosure.

The graph of FIG. 3A provides etch rate data that plots normalized etch rate for SiN layers deposited by PECVD according to embodiments of the disclosure. The PECVD layers are subject to post-deposition exposure to UV radiation, followed by high temperature implantation, and post-implantation annealing by spike anneal at 1000° C. The data of normalized etch rate is plotted for three different implant species, C+, Si+ and Ge+. The normalized etch rate is expressed as a ratio of the etch rate of a given experimental, implanted SiN layer, to the etch rate of a control SiN layer that is deposited under the same PECVD conditions and UV treatment, without being subject to hot implant. The control SiN layer is also subject to a spike anneal at 1000° C. The graph in FIG. 3A is further subdivided to show normalized etch rate as a function of hot implant temperature from relatively lower (L, meaning 150° C.), medium (M, meaning 300° C.), and relatively higher (H, meaning 500° C.). The dashed line at 100% represents the relative etch rate of the control PECVD SiN layer without implant and processed as described above. The etch rate data is also sub-divided to express relative etch rate as a function of implanting species concentration. The etchant recipe in these experiments is based upon a wet etch process using a solution of DHF 100:1 (H₂O:HF) at room temperature.

As illustrated, the SiN layers implanted and annealed according to the present embodiments all exhibit a much lower level of etch rate as compared to the control sample. Note that the Y-axis is the graph of FIG. 3A is expressed on a log scale. Thus, the relative etch rate in most of the experimental SiN layer samples is less than 30% of the etch rate of the control SiN layers that were not implanted. The relative etch rate in the SiN layer also decreases with increasing implant temperature from L to H, and decreases with increasing ion dose (corresponding to increasing implanting species concentration) up to a concentration of at least 7E21/cm³. Moreover, in some examples, the etch rate reduction approaches 99%, such as in the case of carbon ions implanting at relatively higher temperature.

The graph of FIG. 3B provides etch rate data that plots normalized etch rate for SiN layers deposited by PECVD according to additional embodiments of the disclosure. The PECVD layers are subject to post-deposition exposure to UV radiation, followed by high temperature implantation, and post-implantation annealing anneal at 500° C. for five minutes. The data of normalized etch rate is plotted for three different implant species, C+, Si+ and Ge+. The normalized etch rate is expressed as a ratio of the etch rate of a given experimental, implanted SiN layer, to the etch rate of a control SiN layer that is deposited under the same PECVD conditions and UV treatment, without being subject to hot implant. The control SiN layer is also subject to an annealing at 500° C. for five minutes. As with FIG. 3A, the graph in FIG. 3B is further subdivided to show normalized etch rate as a function of hot implant temperature from relatively lower (L), medium (M), and relatively higher (H). The dashed line at 100% represents the relative etch rate of the control PECVD SiN layer without implant and processed as described above. The etch rate data is also sub-divided to express relative etch rate as a function of implanting species concentration. The etchant recipe in these experiments is based upon a wet etch using a solution of DHF 100:1 (H2O:HF) at room temperature.

As with the data of FIG. 3A for spike annealed SiN layers, the SiN layers implanted and annealed at 500 C according to the present embodiments all exhibit a much lower level of etch rate as compared to the control sample. Note that the Y-axis is the graph of FIG. 3B is expressed on a log scale. Thus, the relative etch rate in most of the experimental SiN layer samples is less than 30% of the etch rate of the control SiN layers that were not implanted. The relative etch rate in the SiN layer also decreases with increasing implant temperature from L to H, and decreases with increasing ion dose (corresponding to increasing implanting species concentration) up to a concentration of at least 7E21/cm³.

Moreover, in some examples, the etch rate reduction approaches 99%, such as in the case of carbon ions implanting at relatively higher temperature. Notably, the etch rate reduction engendered by carbon implantation at relatively higher implant temperature (H) and higher implant species concentration (˜6E21/cm³) is greater than the etch rate reduction achieved for the same conditions using silicon implantation or germanium implantation. Thus, while all three different implant species achieve an etch rate reduction of greater than 90% at relatively higher concentration and relatively higher implant temperature, for certain applications requiring extreme etch rate selectivity, hot implantation of carbon ions into a SiN layer may be suitable solution. On the other hand, silicon ion implantation may be suitable to still reduce the etch rate of PECVD SiN layers by greater than 90%, since Si species do not present a contamination concern for processing Si-based semiconductor devices.

While the above results illustrate the reduction of etch rate in hot-implanted-and annealed PECVD nitride layers subjected to a wet etch process, the hot implantation and annealing treatment of PECVD nitride layers of the present embodiments will similarly reduce the etch rate when subjected to a dry etch process, such as RIE. Thus, in different embodiments of the disclosure, the operations of FIG. 1F or FIG. 2F, or similar etch processes, may be implemented either in dry etch processing or in wet etch processing.

Moreover, in additional embodiments, a hot implantation may be used to selectively vary the SiN etch rate in a patterned hard mask structure, for example by directing the implanting species as an angled implant.

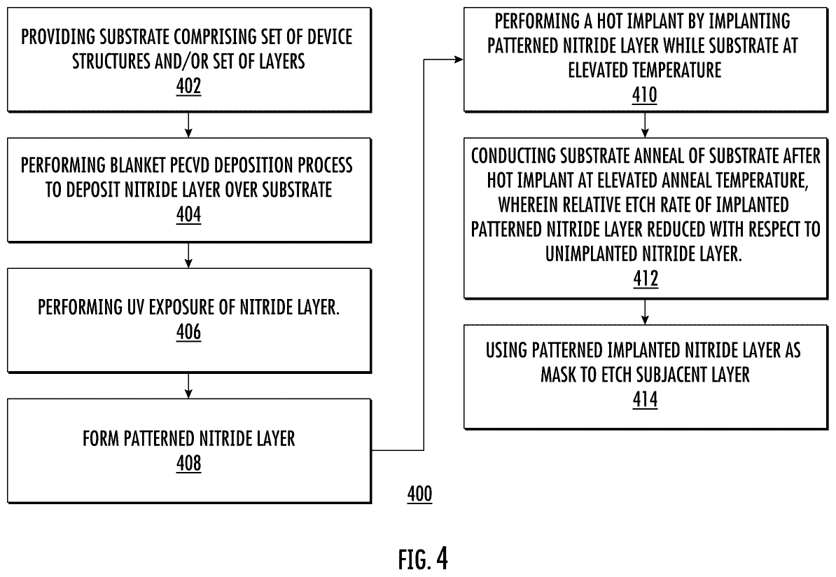

FIG. 4 presents a process flow 400. At block 402, a substrate is provided that may include a semiconductor device, including a plurality of layers, devices, and other features, which structures may be at various stages of fabrication. Such a substrate may include memory devices, logic devices, CMOS devices, and so forth.

At block 404, a blanket deposition process if performed to deposit a nitride layer over the substrate. In some examples, the nitride layer may be a high temperature PECVD silicon nitride layer that is deposited by PECVD. In some examples, the deposition temperature for depositing the PECVD layer may be in a range between 300° C. and 500° C.,

At optional block 406, the nitride layer may be subject to ultraviolet (UV) exposure. The UV exposure may be performed to increase the level of stress in the nitride layer as an example.

At block 408, the nitride layer is patterned to form a patterned nitride layer. The patterning may take place according to known lithographic and etching processes.

At block 410, a hot implant is performed at an elevated substrate temperature to implant species into the substrate. In some embodiments, the hot implant may be an angled implant that is conducted into the patterned nitride layer as shown in FIG. 1C. In another example, the operation at block 408 may be omitted, and the hot implant may not need an angled implant, and may be conducted into a blanket nitride layer, as shown in FIG, 2B. In some examples, the elevated temperature may be up to 700° C. In some examples, where the nitride layer is SiN, the implant species may be one of C, N, Si, or Ge. In some examples, the ion dose of implant species may be such to generate an implant species concentration in the nitride layer of at least 1E20/cm³ and up to 3.5E22/cm³.

At block 412, a substrate anneal after hot implant is conducted at an elevated anneal temperature. The elevated anneal temperature may range from 125° C. to 1100° C. according to some embodiments. At relatively lower anneal temperature, the substrate anneal may be conducted for several seconds up several minutes, up to 10 minutes according to some embodiments. At relatively higher temperature, such as above 800° C., the substrate anneal may be spike anneal where the substrate is heated from room temperature to the designated anneal temperature, and remains at the designated anneal temperature for less than 10 seconds, such as five seconds, two seconds, or less than one second. As such, after the substrate anneal, the nitride layer may exhibit a substantially reduced etch rate with respect to an unimplanted nitride layer, such as an unimplanted silicon nitride layer that is subjected to the same deposition conditions, UV exposure, and anneal recipe. Optionally, the operation at block 412 may be omitted. Note that based upon the relative reduction in etch rate observed according to the aforementioned examples after high temperature implant and post implant thermal treatment, depending upon the amount of etch rate reduction needed for a given application, the desired SiN etch rate reduction may be achieved just with the use of a high temperature implant and no post-implant anneal.

At block 414, the patterned, implanted nitride layer is used as a mask to etch a subjacent layer, such as an oxide layer that is exposed to the etch through openings in the patterned, implanted, nitride layer. Note that in embodiments where block 408 is omitted, after block 412, the (unpatterned, implanted, and annealed) nitride layer will be patterned in a separate operation before the operation of block 414.

In sum, various embodiments that employ a warm to hot implantation (150° C.-550° C.) using C, Si, or Ge provide the advantage of decreasing SiN wet etch rate by at least 70% when ion concentrations as low as 1E21 cm⁻³ are implanted into a nitride layer. This benefit is independent of the subsequent applied anneal thermal budget, such as an anneal at 500° C. for 5 min versus a 1000° C. spike anneal. A second advantage is where the use of a hot C implant may nearly entirely arrest the wet etch rate of a SiN layer. A wet etch rate reduction of 99% is observed at a carbon ion concentration of 6E21 cm⁻³. This benefit is independent of the subsequent applied anneal thermal budget such as an anneal at 500° C. for 5 min versus a 1000° C. spike anneal. A third advantage is related to line edge roughness (LER)/linewidth roughness (LWR) improvement. Hot implant will make the SiN hardmask harder to etch thus allowing a thinner SiN hardmask to be deposited. By having a thinner SiN hardmask, the subsequent dry etching of the underlying material will have improved LER/LWR.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A process to generate an etch-resistant nitride layer, comprising:
providing a substrate, the substrate including a silicon nitride layer formed by PECVD at an elevated deposition temperature;
heating the substrate to an elevated implant temperature;
performing a hot implant by implanting the substrate at the elevated implant temperature, wherein an implanted silicon nitride layer is formed; and
annealing the substrate after the hot implant at an elevated anneal temperature, wherein a relative etch rate of the implanted silicon nitride layer is reduced with respect to an unimplanted silicon nitride layer.

2. The process of claim 1, wherein the silicon nitride layer comprises a silicon nitride layer.

3. The process of claim 1, wherein the silicon nitride layer is deposited at an elevated deposition temperature, between 300° C. and 500° C.

4. The process of claim 1, further comprising subjecting the silicon nitride layer to an ultraviolet exposure after the nitride layer is deposited and before the performing the hot implant.

5. The process of claim 1, wherein the elevated implant temperature is between 150° C. and 700° C.

6. The process of claim 1, wherein the elevated anneal temperature lies between 150° C. and 1100° C.

7. The process of claim 1, wherein, when the substrate is annealed at 500° C. for 5 min after the hot implant, the silicon nitride exhibits a relative decrease in etch rate of at least 70% with respect to a silicon nitride layer that is unimplanted and annealed at 500° C. for 5 min.

8. The process of claim 1, wherein, when the substrate is annealed at 1000° C. in a spike anneal after the hot implant, the silicon nitride layer exhibits a relative decrease in etch rate of at least 70% with respect to a silicon nitride layer that is unimplanted an annealed at 1000° C. in the spike anneal.

9. The process of claim 1, wherein the hot implant is carried out an energy of 0.2 keV to 120 keV, wherein the hot implant comprises an implant species comprising at least one of: carbon, nitrogen, silicon, germanium, helium, neon, and argon.

10. The process of claim 8, wherein the hot implant generates an implant species concentration of 1E20/cm³ or greater.

11. A process to generate an etch-resistant patterned silicon nitride layer, comprising:
providing a substrate having a high temperature PECVD silicon nitride layer;
patterning the high temperature PECVD silicon nitride layer to form a patterned silicon nitride layer;
heating the substrate to an elevated implant temperature; and
performing a hot implant by implanting the substrate at the elevated implant temperature, wherein the patterned silicon nitride layer is exposed to an implant species,
wherein, after the hot implant, a relative etch rate of the patterned silicon nitride layer is reduced with respect to an unimplanted silicon nitride layer.

12. The process of claim 11, wherein the high temperature PECVD silicon nitride layer is deposited at an elevated deposition temperature, between 300° C. and 500° C.

13. The process of claim 11, further comprising subjecting the high temperature PECVD silicon nitride layer to an ultraviolet exposure after the high temperature PECVD silicon nitride is deposited and before the performing the hot implant.

14. The process of claim 11, wherein the elevated implant temperature of the hot implant is between 150° C. and 700° C.

15. The process of claim 11, further comprising subjecting the high temperature PECVD silicon nitride layer to an anneal at a temperature range between 150° C. and 1100° C. after the hot implant.

16. The process of claim 15, wherein, when the substrate is annealed at 500° C. for 5 min after the hot implant, the patterned silicon nitride layer exhibits a relative decrease in etch rate of at least 70% with respect to a silicon nitride layer that is unimplanted and annealed at 500° C. for 5 min.

17. The process of claim 15, wherein, when the substrate is annealed at 1000° C. in a spike anneal after the hot implant, the high temperature PECVD silicon nitride layer exhibits a relative decrease in etch rate of at least 70% with respect to a silicon nitride layer that is unimplanted an annealed at 1000° C. in the spike anneal.

18. The process of claim 11, wherein the hot implant is carried out an energy of 0.2 keV to 120 keV, wherein the hot implant comprises an implant species comprising at least one of: carbon, nitrogen, silicon, germanium, helium, neon, and argon.

19. The process of claim 18, wherein the hot implant generates an implant species concentration of 1E20/cm³ or greater within the patterned silicon nitride layer.

20. The process of claim 11, further comprising performing an etch of the substrate, using the patterned silicon nitride layer as a mask, wherein a layer of the substrate, subjacent to the patterned silicon nitride layer is etched.
